(19) United States
(12) Patent Application Publication
(10) Pub. No.: US 2020/0227469 A1
(43) Pub. Date: Jul. 16, 2020

(54) III-N TRANSISTORS INTEGRATED WITH RESONATORS OF RADIO FREQUENCY FILTERS

(71) Applicant: Intel Corporation, Santa Clara, CA (US)

(72) Inventors: Han Wui Then, Portland, OR (US); Zdravko Boos, Munich (DE); Sansaptak Dasgupta, Hillsboro, OR (US); Marko Radosavljevic, Portland, OR (US); Paul B. Fischer, Portland, OR (US)

(73) Assignee: Intel Corporation, Santa Clara, CA (US)

(21) Appl. No.: 16/249,493

(22) Filed: Jan. 16, 2019

(51) Int. Cl. H01L 27/20; H01L 29/20; H01L 29/78; H01L 41/18; H01L 25/18; H03F 3/195; H03B 5/36

(52) U.S. Cl. CPC H01L 27/20; H01L 29/2003; H01L 29/78; H03B 5/364; H01L 25/18; H03F 3/195; H01L 41/18

(57) ABSTRACT

Disclosed herein are IC structures, packages, and devices that include III-N transistors integrated on the same substrate or die as resonators of RF filters. An example IC structure includes a support structure (e.g., a substrate), a resonator, provided over a first portion of the support structure, and an III-N transistor, provided over a second portion of the support structure. The IC structure includes a piezoelectric material so that first and second electrodes of the resonator enclose a first portion of the piezoelectric material, while a second portion of the piezoelectric material is enclosed between the channel material of the III-N transistor and the support structure. In this manner, one or more resonators of an RF filter may be monolithically integrated with one or more III-N transistors. Such integration may reduce costs and improve performance by reducing RF losses incurred when power is routed off chip.

### BACKGROUND

Radio frequency (RF) filters are important components in modern communication systems. RF filters may be found in mobile computing platforms such as smartphones, tablets, laptops, netbooks, and the like. With the growing number of bands and modes of communications, the number of RF filters in a mobile front-end (FE) can multiply quickly. Resonators such as film bulk acoustic resonator (FBARs) are at the heart of these filters. A single typical RF filter may, e.g., include 7 such resonators arranged in a half -ladder circuit configuration. A typical RF FE covering 2 G/3 G and 4 G may, e.g., include approximately 17 RF filters, resulting in a total of approximately 119 FBARs. With the advent of 5 G in the next few years, RF filters will dominate the costs of RF FE and the total integrated circuit (IC) area available.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 provides a cross-sectional side view illustrating an IC structure that includes an III-N transistor integrated with a resonator of an RF filter, according to some embodiments of the present disclosure.

FIG. 2 provides a cross-sectional side view illustrating an IC structure that includes an III-N transistor with a backside thermal via, integrated with a resonator of an RF filter, according to some embodiments of the present disclosure.

FIG. 3 is a flow diagram of an example method of manufacturing an IC structure that includes an III-N transistor integrated with a resonator of an RF filter, in accordance with various embodiments of the present disclosure.

FIGS. 4A-4G are various views illustrating different example stages in the manufacture of an IC structure that includes an III-N transistor integrated with a resonator of an RF filter using the method of FIG. 3, according to some embodiments of the present disclosure.

FIGS. 5A-5B are top views of a wafer and dies that include one or more IC structures having III-N transistors integrated with resonators of RF filters in accordance with any of the embodiments of the present disclosure.

FIG. 6 is a cross-sectional side view of an IC package that may include one or more IC structures having III-N transistors integrated with resonators of RF filters in accordance with any of the embodiments of the present disclosure.

FIG. 7 is a cross-sectional side view of an IC device assembly that may include one or more IC structures having III-N transistors integrated with resonators of RF filters in accordance with any of the embodiments of the present disclosure.

FIG. 8 is a block diagram of an example computing device that may include one or more IC structures having III-N transistors integrated with resonators of RF filters in accordance with any of the embodiments of the present disclosure.

### DETAILED DESCRIPTION

### Overview

An RF FE typically includes multiple components including RF filters, power amplifiers (PAs), switches, and low-noise amplifiers (LNAs). An RF filter may include one or more, typically a plurality of, resonators, e.g., arranged in a ladder configuration. An individual resonator of an RF filter (in the following referred to as an “RF resonator”) may include a layer of a piezoelectric material such as aluminum nitride (AlN), usually provided by sputtering, enclosed between a bottom electrode and a top electrode, with a cavity provided around a portion of each electrode in order to allow a portion of the piezoelectric material to vibrate during operation of the filter.

Other components of an RF FE, e.g., PAs, switches, and LNAs, may be implemented using transistors. Due, in part, to their large bandgap and high mobility, III-N material based transistors, e.g., gallium nitride (GaN) based transistors, may be particularly advantageous for implementing such components of RF applications, where the term “III-N transistors” is used to describe transistors that employ materials having one or more of group III semiconductor material(s) and nitrogen (N), e.g., GaN, as active materials, e.g., as a channel material of a transistor. For example, because GaN has a larger band gap (about 3.4 electronvolts (eV)) than silicon (Si; bandgap of about 1.1 eV), a GaN transistor is expected to withstand a larger electric field (resulting e.g., from applying a large voltage to the drain, Vdd) before suffering breakdown, compared to a Si transistor of similar dimensions. Furthermore, GaN transistors may advantageously employ a two-dimensional (2D) electron gas (2 DEG), i.e., a group of electrons (an electron gas) free to move in two dimensions but tightly confined in the third dimension (e.g., a 2D sheet charge), as its transport channel, enabling high mobilities without using impurity dopants. For example, the 2D sheet charge may be formed at an abrupt hetero-interface formed by epitaxial deposition, on GaN, of a charge-inducing film of a material having larger spontaneous and piezoelectric polarization, compared to GaN (such a film is generally referred to as a “polarization layer”). Providing a polarization layer on an III-N material such as GaN allows forming very high charge densities, e.g., densities of about 2·10¹³ charges per square centimeter (cm²), without impurity dopants, which, in turn, enables high mobilities, e.g., mobilities greater than about 1000 cm²/(V·s).

Typically, a channel material for an III-N transistor is provided over a crystalline substrate by epitaxial growth, with the crystalline substrate serving as an ordered template for the epitaxial growth of the III-N channel material. Sometimes, a buffer layer may be provided over the substrate, and then the III-N channel material layer is grown over the buffer layer. A buffer layer is a layer of a semiconductor material that has a bandgap larger than that of the channel material, so that the buffer layer can serve to prevent current leakage from the future III-N transistors to the substrate and to enable better epitaxy of the channel material (i.e., to improve epitaxial growth of the channel material in terms of e.g., bridge lattice constant, amount of defects, etc.). For example, GaN may be used as the channel material, while AlGaN may be used as the buffer layer.

Because of these drastically different manufacturing needs and processes used to implement RF filters and III-N transistors of an RF FE, RF filters have, conventionally, been implemented as standalone products, packaged with other RF FE components such as PAs, switches, and LNAs in a multi-chip module. In other words, because of the need for the bottom electrodes and sputtered piezoelectric materials for implementing RF filters, and the need for crystalline substrates to serve as ordered templates for the epitaxial growth of III-N channel materials for implementing III-N transistors, conventionally, RF filters and other RF FE components have been implemented on different substrates.

Disclosed herein are IC structures, packages, and device assemblies that include III-N transistors integrated on the same support structure/material (which may be, e.g., a substrate, a die, or a chip) as resonators of RF filters. Embodiments of the present disclosure are based on recognition that III-N materials used in implementing III-N transistors are also piezoelectric, similar to the piezoelectric material used to implement resonators of RF filters, thereby providing a possibility for integrating III-N transistors on a single support structure with such resonators. In particular, according to various embodiments of the present disclosure, the sputtered piezoelectric material used to form an RF resonator is also used as an ordered template from which epitaxial growth of a channel material for an III-N transistor can originate, instead of a crystalline substrate material as was done in conventional implementations of III-N transistors, advantageously enabling integration of III-N transistors on the same support structure as RF resonators/filters.

In one aspect of the present disclosure, an IC structure is provided, the IC structure including a support structure (e.g., a substrate), an RF resonator provided over a first portion of the support structure, and an III-N transistor provided over a second portion of the support structure. In particular, the IC structure includes a piezoelectric material so that the first and second electrodes of the RF resonator at least partially enclose (sandwich) a first portion of the piezoelectric material, while a second portion of the piezoelectric material is at least partially enclosed between the III-N channel material of the III-N transistor and the support structure (in various embodiments, the first and second portions of the piezoelectric material may include the same or different piezoelectric materials). In this manner, one or more RF resonators may be, advantageously, monolithically integrated with one or more III-N transistors, enabling monolithic integration of all RF FE components, i.e., RF filters, PAs, switches, LNAs, etc., on a single chip. Such integration may reduce costs and improve performance by reducing RF losses incurred when power is routed off chip in a multi-chip module package.

In another aspect of the present disclosure, an IC structure includes an III-N transistor having an III-N channel material provided over the support structure, and further includes a sputtered III-N material between the III-N channel material and the support structure, and an epitaxially grown III-N material between the sputtered III-N material and the III-N channel material. Other aspects of the present disclosure provide other IC structures, IC packages and computing devices that include such IC structures, and methods of manufacturing such IC structures, IC packages and devices. In this manner, III-N transistors may be provided over any support structure, advantageously eliminating the requirement of having crystalline substrates present in the conventional implementations of such transistors.

As used herein, the term “III-N material” refers to a compound semiconductor material with a first sub-lattice of at least one element from group III of the periodic table (e.g., Al, Ga, In) and a second sub-lattice of nitrogen (N). As used herein, the term “III-N device” (e.g., an III-N transistor) refers to a device that includes an III-N material (which may include one or more different III-N materials, e.g., a plurality of different III-N materials stacked over one another) as an active material.

While various embodiments described herein refer to III-N transistors (i.e., transistors employing one or more III-N materials as an active channel material), these embodiments are equally applicable to any other III-N devices besides III-N transistors, such as III-N diodes, sensors, light-emitting diodes (LEDs), and lasers (i.e., other device components employing one or more III-N materials as active materials). Furthermore, while the following discussions may refer to the two-dimensional charge carrier layers as “2 DEG” layers, embodiments described herein are also applicable to systems and material combinations in which 2D hole gas (2 DHG) may be formed, instead of 2 DEG. Thus, unless stated otherwise, embodiments referring to 2 DEG are equally applicable to implementing 2 DHG instead, all of such embodiments being within the scope of the present disclosure.

Each of the structures, packages, methods, devices, and systems of the present disclosure may have several innovative aspects, no single one of which being solely responsible for the all of the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art. For example, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. If used, the terms “oxide,” “carbide,” “nitride,” etc. refer to compounds containing, respectively, oxygen, carbon, nitrogen, etc. Similarly, the terms naming various compounds refer to materials having any combination of the individual elements within a compound (e.g., “gallium nitride” or “GaN” refers to a material that includes gallium and nitrogen, “aluminum indium gallium nitride” or “AlInGaN” refers to a material that includes aluminum, indium, gallium and nitrogen, and so on). Further, the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−20%, preferably within +/−10%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with one or both of the two layers or may have one or more intervening layers. In contrast, a first layer described to be “on” a second layer refers to a layer that is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

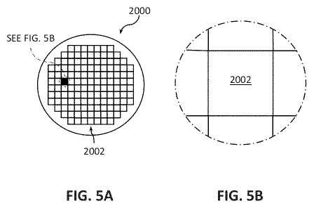

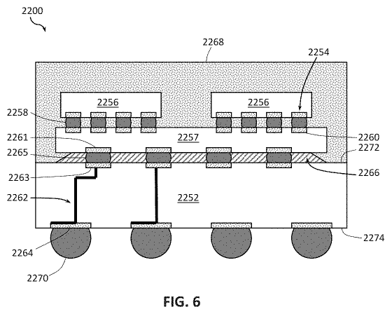

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense. For convenience, if a collection of drawings designated with different letters are present, e.g., FIGS. 5A-5B, such a collection may be referred to herein without the letters, e.g., as “FIG. 5.” In the drawings, same reference numerals refer to the same or analogous elements/materials shown so that, unless stated otherwise, explanations of an element/material with a given reference numeral provided in context of one of the drawings are applicable to other drawings where element/materials with the same reference numerals may be illustrated.

In the drawings, some schematic illustrations of example structures of various structures, devices, and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region(s), and/or occasional dislocation defects of single atoms or clusters of atoms. There may be other defects not listed here but that are common within the field of device fabrication.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Various IC structures that include at least one III-N device (e.g., a III-N transistor) integrated with at least one RF resonator over a single support structure as described herein may be implemented in one or more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on an IC, provided as an integral part of an IC, or those connected to an IC. The IC may be either analog or digital and may be used in a number of applications, such as microprocessors, optoelectronics, logic blocks, audio amplifiers, etc., depending on the components associated with the IC. In some embodiments, IC structures as described herein may be included in a RFIC, which may, e.g., be included in any component associated with an IC of an RF receiver, an RF transmitter, or an RF transceiver, e.g., as used in telecommunications within base stations (BS) or user equipment (UE). Such components may include, but are not limited to, power amplifiers, low-noise amplifiers, RF filters (including arrays of RF filters, or RF filter banks), switches, upconverters, downconverters, and duplexers. In some embodiments, the IC structures as described herein may be employed as part of a chipset for executing one or more related functions in a computer.

Integrating an III-N Transistor with an RF Resonator

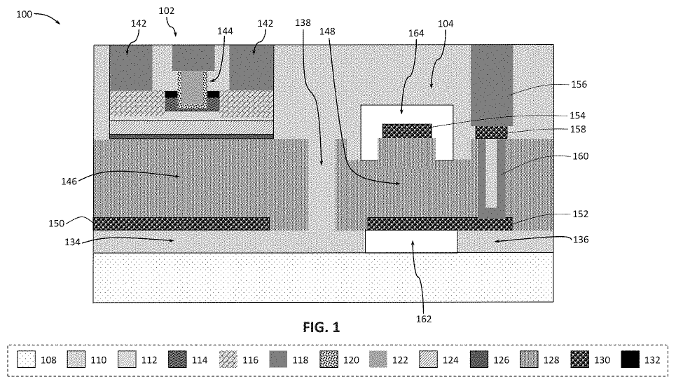

FIG. 1 provides a cross-sectional side view illustrating an IC structure 100 that includes an III-N transistor 102 integrated with a resonator 104 of an RF filter, according to some embodiments of the present disclosure. A legend provided within a dashed box at the bottom of FIG. 1 illustrates colors/patterns used to indicate some classes of materials of some of the elements shown in FIG. 1, so that FIG. 1 is not cluttered by too many reference numerals. For example, FIG. 1 uses different colors/patterns to identify a support structure 108 (which may be referred to, interchangeably, as a “substrate 108”), an insulator 110, an III-N channel material 112, a polarization material 114, source/drain (S/D) regions 116, an electrically conductive material 118 used to implement contacts to various electrodes, a gate dielectric material 120, a gate electrode material 122, a buffer layer material 124, an epitaxially grown piezoelectric III-N material 126, a sputtered piezoelectric III-N material 128, an electrically conductive material 130 used to implement various electrodes, and a hard-mask material 132.

The support structure 108 may be any suitable structure, e.g., a substrate, a die, or a chip, on which RF resonators and III-N transistors as described herein may be implemented. In some embodiments, the support structure 108 may include a semiconductor, such as silicon. In other implementations, the support structure 108 may include/be alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-N or group IV materials.

In some embodiments, the support structure 108 may include a ceramic material, or any other non-semiconductor material. For example, in some embodiments, the support structure 108 may include glass, a combination of organic and inorganic materials, embedded portions having different materials, etc. Although a few examples of materials from which the support structure may be formed are described here, any material that may serve as a foundation upon which at least RF resonators and III-N transistors as described herein may be built falls within the spirit and scope of the present disclosure.

In some embodiments, the support structure 108 may include an insulating layer, such as an oxide isolation layer. For example, in the embodiment of FIG. 1, a layer of the insulator 110 is shown to be provided over the support structure 108. The insulator 110 may include any suitable insulating material, e.g., any suitable interlayer dielectric (ILD), to electrically isolate the semiconductor material of the support structure 108 from other regions of or surrounding the III-N transistor 102 and/or from other regions of or surrounding the resonator 104. Providing such an insulating layer over the support structure 108 may help mitigate the likelihood that conductive pathways will form through the support structure 108 (e.g., a conductive pathway between the source and drain regions 116). Examples of the insulator 110 may include, in some embodiments, silicon oxide, silicon nitride, aluminum oxide, and/or silicon oxynitride. In general, FIG. 1 illustrates that the insulator 110 may be provided in various portions of the IC structure 100, such as a portion 134 provided between the III-N transistor 102 and the support structure 108, a portion 136 provided between the RF resonator 104 and the support structure 108, and a portion 138 provided between the RF resonator 104 and the III-N transistor 102. In various embodiments, the insulator 110 may include different insulating materials in different portions of the IC structure 100.

In some embodiments, the III-N channel material 112 may be formed of a compound semiconductor with a first sub-lattice of at least one element from group III of the periodic table (e.g., Al, Ga, In), and a second sub-lattice of nitrogen (N). In some embodiments, the III-N channel material 112 may be a binary, ternary, or quaternary III-N compound semiconductor that is an alloy of two, three, or even four elements from group III of the periodic table (e.g., boron, aluminum, indium, gallium) and nitrogen.

In general, the III-N channel material 112 may be composed of various III-N semiconductor material systems including, for example, N-type or P-type III-N materials systems, depending on whether the transistor 102 is an N-type or a P-type transistor. For some N-type transistor embodiments, the III-N channel material 112 may advantageously be an III-N material having a high electron mobility, such as, but not limited to GaN, InGaAs, InP, InSb, and InAs. For some InₓGa₁₋ₓAs embodiments, In content (x) may be between 0.6 and 0.9, and advantageously is at least 0.7 (e.g., In_{0.7}Ga_{0.3}As). For some such embodiments, the III-N channel material 112 may be a ternary III-N alloy, such as InGaN, or a quaternary III-N alloy, such as AlInGaN.

In some embodiments, the III-N channel material 112 may be formed of a highly crystalline semiconductor, e.g., of substantially a monocrystalline semiconductor (possibly with some limited amount of defects, e.g., dislocations). The quality of the III-N channel material 112 (e.g., in terms of defects or crystallinity) may be higher than that of other III-N materials of, or near, the III-N transistor 102 since, during the operation of the III-N transistor 102, a transistor channel will form in the III-N channel material 112.

In some embodiments, the III-N channel material 112 may be an intrinsic III-N semiconductor material or alloy, not intentionally doped with any electrically active impurity. In alternate embodiments, one or more a nominal impurity dopant level may be present within the III-N channel material 112, for example to set a threshold voltage Vt of the transistor 102, or to provide halo pocket implants, etc. In such impurity-doped embodiments however, impurity dopant level within the III-N channel material 112 may be relatively low, for example below 10¹⁵ dopants per cubic centimeter (cm⁻³), or below 10¹³ cm⁻³.

In various embodiments, a thickness of the III-N channel material 112 may be between about 5 and 2000 nanometers, including all values and ranges therein, e.g., between about 50 and 1000 nanometers, or between about 10 and 50 nanometers. Unless specified otherwise, all thicknesses described herein refer to a dimension measured in a direction perpendicular to the support structure 108.

Turning now to the polarization material 114 of the III-N transistor 102, in general, the polarization material 114 may be a layer of a charge-inducing film of a material having larger spontaneous and/or piezoelectric polarization than that of the bulk of the III-N layer material immediately below it (e.g., the III-N channel material 112), creating a heterojunction (hetero-interface) with the III-N channel material 112, and leading to formation of 2 DEG at or near (e.g., immediately below) that interface, during operation of the transistor 102. As described above, a 2 DEG layer may be formed during operation of an III-N transistor in a layer of an III-N semiconductor material immediately below a suitable polarization layer. In various embodiments, the polarization material 114 may include materials such as AlN, InAlN, AlGaN, or AlₓIn_{y}Ga_{1-x-y}N, and may have a thickness between about 1 and 50 nanometers, including all values and ranges therein, e.g., between about 5 and 15 nanometers or between about 10 and 30 nanometers.

As also shown in FIG. 1, the III-N transistor 102 may include two S/D regions 116, where one of the S/D regions 116 is a source region and another one is a drain region, where the source and drain designations may be interchangeable. As is well-known, in a transistor, S/D regions (also sometimes interchangeably referred to as “diffusion regions”) are regions that can supply charge carriers for the transistor channel (e.g., the transistor channel 112) of the transistor (e.g., the III-N transistor 102). In some embodiments, the S/D regions 116 may include highly doped semiconductor materials, such as highly doped InGaN. Often, the S/D regions may be highly doped, e.g., with dopant concentrations of at least above 1·10²¹ cm⁻³, in order to advantageously form Ohmic contacts with the respective S/D electrodes of the III-N transistor 102 (e.g., electrodes 142 shown in FIG. 1, made of the electrically conductive material 118), although these regions may also have lower dopant concentrations in some implementations. Regardless of the exact doping levels, the S/D regions 116 are the regions having dopant concentration higher than in other regions between the source region (e.g., the region 116 shown on the left side in FIG. 1) and the drain region (e.g., the region 116 shown on the right side in FIG. 1), i.e., higher than the III-N channel material 112. For that reason, sometimes the S/D regions are referred to as highly doped (HD) S/D regions. In further embodiments, one or more layers of metal and/or metal alloys may be used to form the S/D regions 116.

The electrically conductive material 118 of the S/D electrodes 142 may include any suitable electrically conductive material, alloy, or a stack of multiple electrically conductive materials. In some embodiments, the S/D electrodes 142 may include one or more metals or metal alloys, with metals such as copper, ruthenium, palladium, platinum, cobalt, nickel, hafnium, zirconium, titanium, tantalum, and aluminum, tantalum nitride, titanium nitride, tungsten, doped silicon, doped germanium, or alloys and mixtures of these. In some embodiments, the S/D electrodes 142 may include one or more electrically conductive alloys, oxides, or carbides of one or more metals. In some embodiments, the S/D electrodes 142 may include a doped semiconductor, such as silicon or another semiconductor doped with an N-type dopant or a P-type dopant. Metals may provide higher conductivity, while doped semiconductors may be easier to pattern during fabrication. In some embodiments, the S/D electrodes 142 may have a thickness between about 2 nanometers and 1000 nanometers, preferably between about 2 nanometers and 100 nanometers.

FIG. 1 further illustrates a gate stack 144 provided over the channel portion of the III-N channel material 112. The gate stack 144 includes a layer of a gate dielectric material 120, and a gate electrode material 122.

The gate dielectric material 120 is typically a high-k dielectric material, e.g., a material including elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric material 120 may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, an annealing process may be carried out on the gate dielectric material 120 during manufacture of the transistor 102 to improve the quality of the gate dielectric material 120. A thickness of the gate dielectric material 120 may be between 0.5 nanometers and 3 nanometers, including all values and ranges therein, e.g., between 1 and 3 nanometers, or between 1 and 2 nanometers.

The gate electrode 122 may include at least one P-type work function metal or N-type work function metal, depending on whether the transistor 102 is a PMOS transistor or an NMOS transistor (e.g., P-type work function metal may be used as the gate electrode 122 when the transistors 102 is a PMOS transistor and N-type work function metal may be used as the gate electrode 122 when the transistor 102 is an NMOS transistor, depending on the desired threshold voltage). For a PMOS transistor, metals that may be used for the gate electrode material 122 may include, but are not limited to, ruthenium, palladium, platinum, cobalt, nickel, titanium nitride, and conductive metal oxides (e.g., ruthenium oxide). For an NMOS transistor, metals that may be used for the gate electrode 122 include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and nitrides of these metals (e.g., tantalum nitride, and tantalum aluminum nitride). In some embodiments, the gate electrode material 122 may include a stack of two or more metal layers, where one or more metal layers are work function metal layers and at least one metal layer is a fill metal layer.

Further layers may be included next to the gate electrode material 122 for other purposes, such as to act as a diffusion barrier layer or/and an adhesion layer, not specifically shown in FIG. 1. Furthermore, in some embodiments, the gate dielectric material 120 and the gate electrode material 122 may be surrounded by a gate spacer, not shown in FIG. 1, configured to provide separation between the gates of different transistors. Such a gate spacer may be made of a low-k dielectric material (i.e., a dielectric material that has a lower dielectric constant (k) than silicon dioxide which has a dielectric constant of 3.9). Examples of low-k materials that may be used as the dielectric gate spacer may include, but are not limited to, fluorine-doped silicon dioxide, carbon-doped silicon dioxide, spin-on organic polymeric dielectrics such as polyimide, polynorbornenes, benzocyclobutene, and polytetrafluoroethylene (PTFE), or spin-on silicon-based polymeric dielectric such as hydrogen silsesquioxane (HSQ) and methylsilsesquioxane (MSQ)). Other examples of low-k materials that may be used as the dielectric gate spacer include various porous dielectric materials, such as for example porous silicon dioxide or porous carbon-doped silicon dioxide, where large voids or pores are created in a dielectric in order to reduce the overall dielectric constant of the layer, since voids can have a dielectric constant of nearly 1.

In some embodiments, the IC structure 100 may, optionally, include a buffer material 124 between the III-N channel material 112 and the rest of the III-N materials below the buffer material 124 (i.e., the epitaxially grown III-N material 126 and the sputtered III-N material 128). Such a buffer layer may be included to electrically isolate the semiconductor materials that are the epitaxially grown III-N material 126 and the sputtered III-N material 128 from the III-N channel material 112, and, thereby, mitigate the likelihood that conductive pathways will form between, e.g., a source and a drain regions of the III-N transistor 102, or between neighboring III-N transistors (not specifically shown in FIG. 1), through the epitaxially grown III-N material 126 and the sputtered III-N material 128. In some embodiments, the buffer material 124 may be a layer of a semiconductor material that has a bandgap larger than that of the III-N channel material 112, so that the buffer material 124 can serve to prevent current leakage from the future III-N transistors to the epitaxially grown III-N material 126 and the sputtered III-N material 128. A properly selected semiconductor for the buffer material 124 may also enable better epitaxy of the III-N channel material 112 thereon, e.g., it may improve epitaxial growth of the III-N channel material 112, for instance in terms of a bridge lattice constant or amount of defects. For example, a semiconductor that includes aluminum, gallium, and nitrogen (e.g., AlGaN) or a semiconductor that includes aluminum and nitrogen (e.g., AlN) may be used as the buffer material 124 when the III-N channel material 112 is a semiconductor that includes gallium and nitrogen (e.g., GaN). Other examples of materials for the buffer material 124 may include materials typically used as ILD, described above, such as oxide isolation layers, e.g., silicon oxide, silicon nitride, aluminum oxide, and/or silicon oxynitride. When implemented in the III-N transistor 102, the buffer material 124 may have a thickness between about 100 and 5000 nm, including all values and ranges therein, e.g., between about 200 and 1000 nanometers, or between about 250 and 500 nanometers.

The epitaxially grown piezoelectric material 126 and a portion of the sputtered piezoelectric material 128 that is below the III-N channel material 112 may be considered to be a part of the III-N transistor 102. As shown in FIG. 1, the sputtered piezoelectric material 128 may be disposed between the epitaxially grown piezoelectric material 126 and the support structure 108, while the epitaxially grown piezoelectric material 126 may be disposed between the sputtered piezoelectric material 128 and the III-N channel material 112 (or the buffer material 124, in case the buffer layer is used). As the names suggest, the epitaxially grown piezoelectric material 126 is a material provided by epitaxial deposition/growth (e.g., using chemical vapor deposition (CVD), e.g., using metalorganic CVD (MOCVD)), while the sputtered piezoelectric material 128 is a material provided by sputtering. In various embodiments, both materials 126 and 128 may include substantially the same chemical compositions, e.g., both may include an III-N material such as, e.g., AlN, but different methods of their deposition result in different characteristics of these materials. In particular, the epitaxially grown material 122 may be a substantially single crystalline material, possibly defective, i.e., including a certain amount of dislocations, while the sputtered material 128 may include a plurality of different crystalline domains (i.e., the sputtered material 128 is not a single crystalline material), a difference that will be readily visible in an image of a suitable characterization tool, e.g., in a TEM image. As a result of different crystallinity of the materials 126 and 128, their X-ray diffraction (another characterization tool) peaks will be different. In some embodiments, a full width half maximum (FWHM) of an X-ray diffraction peak of the epitaxially grown material 126 may be less than 2 degrees, while the FWHM of an X-ray diffraction peak of the sputtered material 128 may be equal to or greater than 2 degrees. In other embodiments, the threshold value could be different than 2 degrees, which is just a rule-of-thumb value. In general, a FWHM of an X-ray diffraction peak of the epitaxially grown material 126 may be less than a FWHM of an X-ray diffraction peak of the sputtered material 128, indicating their different crystalline properties due to the different techniques used to deposit these materials (epitaxial growth and sputtering, respectively).

The sputtered material 128 may, advantageously, be deposited over any surface, e.g., over the insulator 110, over the support structure 108, and/or over the electrically conductive material 130. While the quality of the sputtered III-N material 128 may not be sufficiently high to serve as the III-N channel material, the sputtered material 128 may serve as a foundation or template for epitaxially growing the material 128 thereon, where the epitaxially grown material 128 will have a much better quality. Also, the sputtered material 128 that is used as a template for epitaxially growing the material 128 and then providing other components of the III-N transistor 102, may be the same material, e.g., deposited in a single deposition step, as the sputtered piezoelectric material provided between the bottom and top electrodes of the RF resonator 104, thus enabling integration of the III-N transistor 102 and the RF resonator 104 on a single substrate 108. FIG. 1 illustrates a first portion 146 being a portion of the sputtered material 128 that serves as a template for epitaxially growing the material 128 and then providing other components of the III-N transistor 102, and a second portion 148 being a portion of the sputtered material 128 that is included between the bottom and top electrodes of the RF resonator 104. While, in some embodiments, portions 146 and 148 may be made from the sputtered material 128 deposited in a single deposition step, descriptions provided herein are equally applicable to portions 146 and 148 being made from different sputtered piezoelectric III-N materials 128. In various embodiments, a thickness of the sputtered material 128 may be between about 100 and 2000 nanometers, including all values and ranges therein, while a thickness of the epitaxially grown material 126 may be between about 10 and 200 nanometers, e.g., between about 20 and 50 nanometers.

As also shown in FIG. 1, the III-N transistor 102 may further, optionally, include the hard-mask material 132, which could include one or more of silicon nitride, carbon-doped silicon nitride, silicon oxide, or silicon oxynitride. In various embodiments, a thickness of the hard-mask material 132 may be between about 5 and 500 nanometers, including all values and ranges therein, e.g., between about 10 and 100 nanometers.

FIG. 1 further illustrates that, optionally, a portion 150 of an electrically conductive material may be provided between the sputtered portion 146 and the support structure 108. In some embodiments, the portion 150 may serve to dissipate heat generated by the transistor 102 because typically, electrically conductive materials also have high thermal conductivity. In such embodiments, the portion 150 may be coupled to a heat sink (not specifically shown in FIG. 1), and not be electrically connected to any potential.

Although not specifically shown in FIG. 1, the IC structure 100 may further include additional transistors similar to the III-N transistor 102, described above.

Turning now to the RF resonator 104, FIG. 1 illustrates that the resonator 104 may include a bottom electrode 152, a top electrode 154. In various embodiments, the bottom electrode 152 and the top electrode 154 may be of the same or different electrically conductive electrode material(s) 130, which materials may include any of the materials listed above with reference to the electrically conductive material 118.

Elements shown in FIG. 1 with reference numerals 156, 158, and 160 illustrate an example of how electrical connection to the bottom electrode 152 can be made. Electrical connection to the top electrode 154 can be made out of the plane of the drawing and, therefore, is not shown in FIG. 1. Of course, in other embodiments, electrical connections to the electrodes 152, 154 can be arranged differently (the same holds for electrical connections to other electrically conductive materials shown in FIG. 1, such as to S/D contacts 142).

In order to build an RF resonator, a piezoelectric material is sandwiched between the bottom electrode 152 and the top electrode 154, shown in FIG. 1 with the portion 148 of the sputtered material 128 being disposed between the bottom electrode 152 and the top electrode 154. Furthermore, in order to allow the piezoelectric portion 148 to vibrate, appropriate cavities are to be provided around the bottom and top electrodes 152 and 154, shown in FIG. 1 as cavities 162 and 164, respectively.

The thickness of the piezoelectric material portion 148 between the bottom and top electrodes 152, 154 of the resonator 104 may be inversely proportional to the resonance frequency of the resonator and may, therefore, be selected based on the desired cellular band for the operation of RF filter implementing such a resonator. For example, for a 2-4 gigahertz (GHz) cellular band, the thickness of the piezoelectric material portion 148 may be between about 1 and 2 micrometer (micron), while, for a 10-20 GHz band, the thickness of the piezoelectric material may be on the order of hundreds of nanometers, rather than micron. As described above, in some embodiments, the portion 148 could be made in a single sputtering process as the portion 146. In some such embodiments, the considerations for the desired cellular band operation of the RF resonator 104 may be decisive in selecting the thickness of these portions. In other embodiments when the portions 146 and 148 are made in a single sputtering process, thickness of the portion 148 may be further modified (e.g., reduced or increased) compared to the thickness of the portion 146.

Although not specifically shown in FIG. 1, the IC structure 100 may further include additional resonators similar to the RF resonator 104, described above. In some embodiments, an RF filter may include a plurality of such resonators, all of which included on a single substrate in the modified version of the IC structure 100 (i.e., modified to include more resonators 104).

In various embodiments, the IC structure 100 may be included in, or used to implement at least a portion of an RF FE.

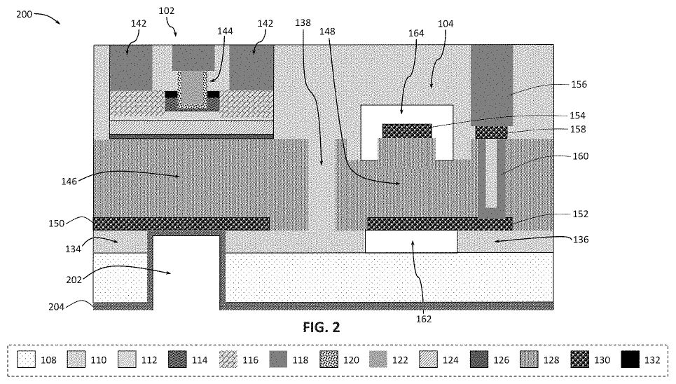

FIG. 2 provides a cross-sectional side view illustrating an IC structure 200 that includes an III-N transistor integrated with a RF resonator, but now also including a backside thermal via 202, according to some embodiments of the present disclosure. The IC structure 200 is similar to the IC structure 100 and, therefore, descriptions provided for the IC structure 100 are applicable to the IC structure 200 and, in the interests of brevity, are not repeated here. Instead, only the differences are described. As shown in FIG. 2, the backside thermal via 202 may be a vial lined with a thermally conductive material 204, and may be thermally coupled to the portion 150. Such an implementation may provide improved heat dissipation for the III-N transistor 102 and/or the IC structure 200 as a whole.

The IC structures illustrated in FIGS. 1-2 do not represent an exhaustive set of assemblies in which one or more III-N transistors 102 may be integrated with one or more RF resonators 104 over a single substrate 108, as described herein, but merely provide examples of such structures/assemblies. Although particular arrangements of materials are discussed with reference to FIGS. 1-2, intermediate materials may be included in various portions of these FIGS. Note that FIGS. 1-2 are intended to show relative arrangements of some of the components therein, and that various device components of these FIGS. may include other components that are not specifically illustrated, e.g., various interfacial layers or various additional layers or elements. For example, although not specifically shown, the IC structure 100 may include a solder resist material (e.g., polyimide or similar material) and one or more bond pads formed on upper-most interconnect layer of the IC structure, e.g., at the top of the IC structure 100 shown in FIG. 1. The bond pads may be electrically coupled with a further interconnect structure and configured to route the electrical signals between the III-N transistor 102 and other external devices, and/or between the RF resonator 104 and other external devices. For example, solder bonds may be formed on the one or more bond pads to mechanically and/or electrically couple a chip including the IC structure 100 with another component (e.g., a circuit board). The IC structure 100 may have other alternative configurations to route the electrical signals from the interconnect layers, e.g., the bond pads described above may be replaced by or may further include other analogous features (e.g., posts) that route the electrical signals to external components.

Additionally, although some elements of the IC structures are illustrated in FIGS. 1-2 as being planar rectangles or formed of rectangular solids, this is simply for ease of illustration, and embodiments of various ones of these elements may be curved, rounded, or otherwise irregularly shaped as dictated by, and sometimes inevitable due to, the manufacturing processes used to fabricate semiconductor device assemblies. For example, while FIGS. 1-2 may illustrate various elements, e.g., the S/D regions 116, the S/D contact regions 142, the portion 138, etc., as having perfectly straight sidewall profiles, i.e., profiles where the sidewalls extend perpendicularly to the support structure 108, these idealistic profiles may not always be achievable in real-world manufacturing processes. Namely, while designed to have straight sidewall profiles, real-world openings which may be formed as a part of fabricating various elements of the IC structures shown in FIGS. 1-2 may end up having either so-called “re-entrant” profiles, where the width at the top of the opening is smaller than the width at the bottom of the opening, or “non-re-entrant” profile, where the width at the top of the opening is larger than the width at the bottom of the opening. Oftentimes, as a result of a real-world opening not having perfectly straight sidewalls, imperfections may form within the materials filling the opening. For example, typical for re-entrant profiles, a void may be formed in the center of the opening, where the growth of a given material filling the opening pinches off at the top of the opening. Therefore, descriptions of various embodiments of integrating one or more III-N transistors with one or more RF resonators provided herein are equally applicable to embodiments where various elements of such integrated structures look different from those shown in the FIGS. due to manufacturing processes used to form them.

Inspection of layout and mask data and reverse engineering of parts of a device to reconstruct the circuit using e.g., optical microscopy, TEM, or SEM, and/or inspection of a cross-section of a device to detect the shape and the location of various device elements described herein using e.g., Physical Failure Analysis (PFA) would allow determination of the integration of one or more III-N transistors with one or more RF resonators as described herein.

Manufacturing III-N Transistors Integrated with RF Resonators

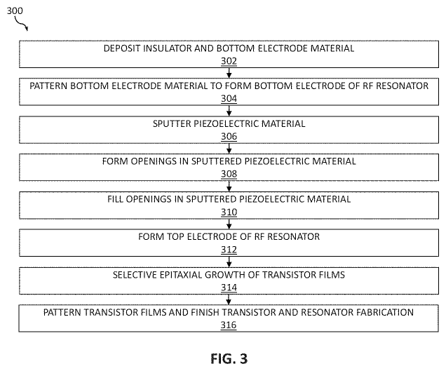

The IC structures implementing one or more III-N transistors integrated with one or more RF resonators as described herein may be manufactured using any suitable techniques. Broadly, a method of manufacturing any of the IC structures described herein may include providing a piezoelectric material (e.g., the sputtered material 128) over a support structure (e.g., the support structure 108), providing an RF resonator (e.g., the resonator 104), where the RF resonator includes a first and a second electrodes (e.g., the electrodes 152 and 154), and a portion (e.g., the portion 148) of the piezoelectric material between the first and the second electrodes, and providing an III-N transistor (e.g., the transistor 102), where a portion (e.g., the portion 146) of the piezoelectric material is between the III-N transistor and the support structure. In such a method, processes for forming portions of an RF resonator may be interleaved, or at least partially concurrent, with processed for forming portions of an III-N transistor over the same substrate. One example of such a method is shown in FIG. 3. However, other examples of manufacturing any of the IC structures described herein, as well as larger devices and assemblies that include such structures (e.g., as shown in FIGS. 6-8) are also within the scope of the present disclosure.

FIG. 3 is a flow diagram of an example method 300 of manufacturing an IC structure that includes an III-N transistor integrated with an RF resonator, in accordance with various embodiments of the present disclosure.

Although the operations of the method 300 are illustrated once each and in a particular order, the operations may be performed in any suitable order and repeated as desired. For example, one or more operations may be performed in parallel to manufacture, substantially simultaneously, multiple III-N transistors and/or multiple RF resonators as described herein. In another example, the operations may be performed in a different order to reflect the structure of a particular device assembly in which one or more III-N transistors integrated with one or more RF resonators as described herein will be included.

In addition, the example manufacturing method 300 may include other operations not specifically shown in FIG. 3, such as various cleaning or planarization operations as known in the art. For example, in some embodiments, the support structure 108, as well as layers of various other materials subsequently deposited thereon, may be cleaned prior to, after, or during any of the processes of the method 300 described herein, e.g., to remove oxides, surface-bound organic and metallic contaminants, as well as subsurface contamination. In some embodiments, cleaning may be carried out using e.g., a chemical solutions (such as peroxide), and/or with ultraviolet (UV) radiation combined with ozone, and/or oxidizing the surface (e.g., using thermal oxidation) then removing the oxide (e.g., using hydrofluoric acid (HF)). In another example, the structures/assemblies described herein may be planarized prior to, after, or during any of the processes of the method 300 described herein, e.g., to remove overburden or excess materials. In some embodiments, planarization may be carried out using either wet or dry planarization processes, e.g., planarization be a chemical mechanical planarization (CMP), which may be understood as a process that utilizes a polishing surface, an abrasive and a slurry to remove the overburden and planarize the surface.

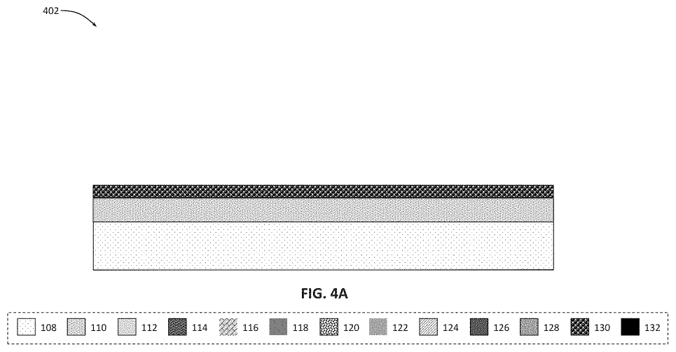

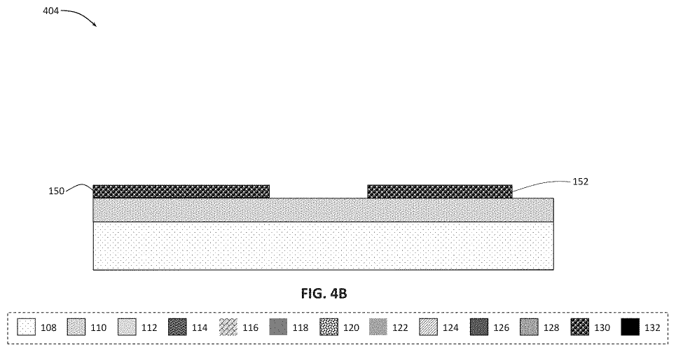

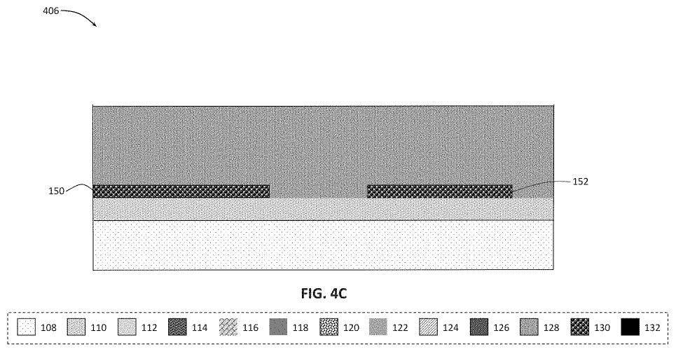

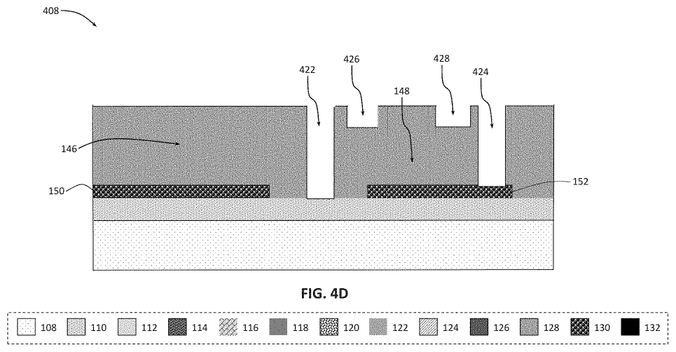

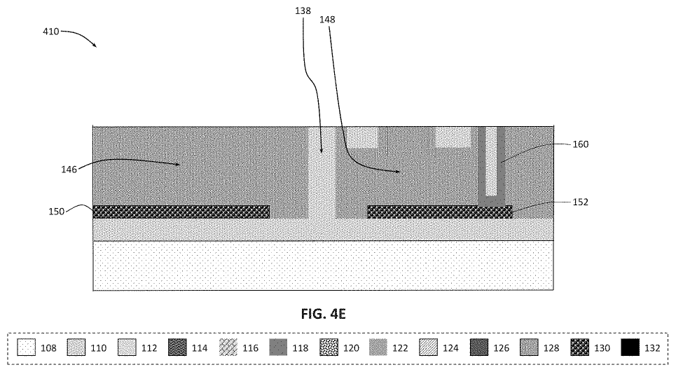

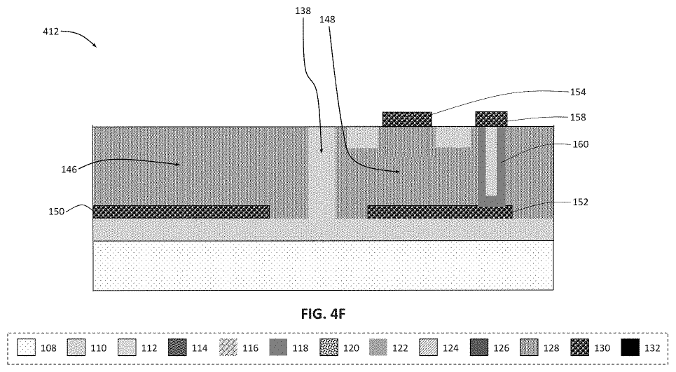

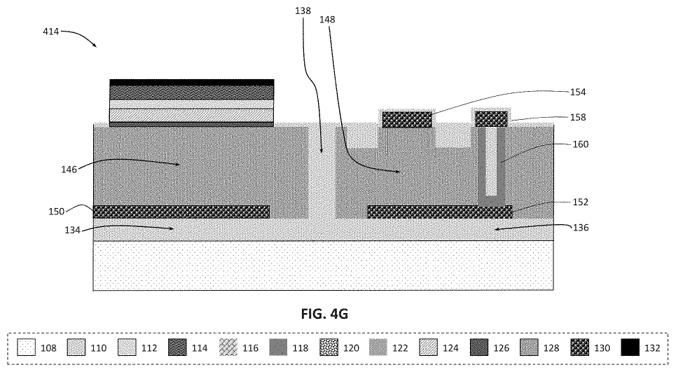

Various operations of the method 300 may be illustrated with reference to the example embodiments shown in FIGS. 4A-4G, illustrating fabrication of an IC structure as shown in FIG. 1, but the method 300 may be used to manufacture any suitable IC structures having one or more III-N transistors integrated with one or more RF resonators according to any embodiments of the present disclosure. FIGS. 4A-4G illustrate cross-sectional side views similar to the view shown in FIG. 1, in various example stages in the manufacture of an IC structure using the method of FIG. 3 in accordance with some embodiments of the present disclosure.

The method 300 may begin with providing a layer of an insulator material over a substrate, and further providing a layer of a bottom electrode material over the insulator material (process 302 shown in FIG. 3, a result of which is illustrated with an IC structure 402 shown in FIG. 4A). The IC structure 402 illustrates the support structure 108 and a layer of the insulator 110 provided thereon, and further illustrates a layer of the electrically conductive material 130 provided over the insulator 110. The layers may include materials and have thicknesses as described above with reference to these portions of the IC structure 100. In various embodiments, any suitable deposition techniques may be used to deposit and a layer of the insulator 110 and a layer of the bottom electrode material 130. Examples of deposition techniques that may be used to provide a layer of the insulator 110 include, but are not limited to, spin-coating, dip-coating, atomic layer deposition (ALD), physical vapor deposition (PVD) (e.g., evaporative deposition, magnetron sputtering, or e-beam deposition), or CVD. Examples of deposition techniques that may be used to provide a layer of the bottom electrode material 130 include, but are not limited to, ALD, PVD (including sputtering), CVD, or electroplating.

The method 300 may then proceed with patterning the bottom electrode layer deposited in 302 to form one or more bottom electrodes (process 304 shown in FIG. 3, a result of which is illustrated with an IC structure 404 shown in FIG. 4B). The IC structure 404 illustrates that the layer of the bottom electrode material 130 is patterned to form the bottom electrode 152 for the future RF resonator, as well as the portion 150 to be below the future III-N transistor, as described above. In various embodiments, any suitable patterning techniques may be used in the process 304, such as, but not limited to, photolithographic or electron-beam (e-beam) patterning, possibly in conjunction with a suitable etching technique, e.g., a dry etch, such as RF reactive ion etch (RIE) or inductively coupled plasma (ICP) RIE. In some embodiments, the etch performed in the process 304 may include an anisotropic etch, using etchants in a form of e.g., chemically active ionized gas (i.e., plasma) using e.g., bromine (Br) and chloride (Cl) based chemistries. In some embodiments, during the etch of the process 304, the IC structure may be heated to elevated temperatures, e.g., to temperatures between about room temperature and 200 degrees Celsius, including all values and ranges therein, to promote that byproducts of the etch are made sufficiently volatile to be removed from the surface.

Next, the method 300 may include sputtering a layer of a piezoelectric material, e.g., an III-N material, over the one or more bottom electrodes formed in the process 304 (process 306 shown in FIG. 3, a result of which is illustrated with an IC structure 406 shown in FIG. 4C). The IC structure 406 illustrates a layer of the sputtered material 128 provided over the bottom electrode 152 and the portion 150. The layer deposited in process 306 may include materials and have thicknesses as described above with reference to the sputtered material 128.

The method 300 may then proceed with forming one or more openings in the layer of the sputtered material 128 provided in process 306 (process 308 shown in FIG. 3, a result of which is illustrated with an IC structure 408 shown in FIG. 4D). The IC structure 408 illustrates an opening 422 (which may be referred to as a “deep isolation trench”) for electrically isolating the III-N transistor 102 from the RF resonator 104. The IC structure 408 further illustrates an opening 424 (which may be referred to as a “deep trench”) for providing electrical contact to the bottom electrode 152 of the RF resonator 104. Still further, the IC structure 408 illustrates openings 426 and 428 (which may be referred to as “shallow trenches”) for forming a portion 430 of the sputtered material 128 that protrudes from the adjacent portions (the ones at the bottom of the openings 426 and 428) for housing the top electrode 154 thereon, provided at a later process. In various embodiments, any suitable techniques may be used for forming the openings in the process 308, e.g., patterning and etching techniques described above with reference to the process 304.

The method 300 may then proceed with filling the openings formed in the process 308 with desired materials (process 310 shown in FIG. 3, a result of which is illustrated with an IC structure 410 shown in FIG. 4E). The IC structure 410 illustrates that the opening 422 is filled with the insulator 110, so that the portion 138 of the insulator 110 provides electrical isolation between the sputtered material portion 146 under the III-N transistor 102 and the sputtered material portion 148 under the RF resonator 104. The IC structure 410 further illustrates that the openings 426 and 428 are also filled with the insulator 110. Further, the IC structure 410 illustrates that the opening 424 is lined with a layer of an electrically conductive material, e.g., tungsten, titanium nitride, tantalum nitride, titanium, or any of the electrically conductive materials described with reference to the material 118, and then filled with the insulator 110. In some embodiments, lining of the opening 424 with an electrically conductive material may be performed using any suitable conformal deposition technique, e.g., using CVD or ALD. In other embodiments, the opening 424 may be lined with an electrically conductive material, but the remainder of the opening 424 does not have to be filled with any materials and may be left void. In still other embodiments, the opening 424 may be completely filled with the electrically conductive material instead of only being lined with said material. The insulator 110 may be deposited in the process 310 using any of the deposition techniques described above with reference to the process 302.

Further, the method 300 may proceed with forming a top electrode for the future RF resonator 104 (process 312 shown in FIG. 3, a result of which is illustrated with an IC structure 412 shown in FIG. 4F). The IC structure 412 illustrates the top electrode 154 and an electrically conductive element 158 formed from the electrode material 130. In various embodiments, any suitable deposition and patterning techniques may be used in the process 312, such as, but not limited to, those described with reference to the processes 302 and 304 for forming the bottom electrode 152.

The method 300 may proceed with epitaxially growing various transistor films for forming the future III-N transistor 102 (process 314 shown in FIG. 3, a result of which is illustrated with an IC structure 414 shown in FIG. 4G). In this context, “epitaxial growth” refers to the deposition of crystalline overlayers in the form of the desired materials on the surface of the sputtered piezoelectric material 128 which provides an ordered template for the growth. The epitaxial growth of various layers of the process 314 may be carried out using any known gaseous or liquid precursors for forming the desired material layers. The IC structure 414 illustrates a layer of the epitaxially grown piezoelectric material 126 grown over the upper surface of the sputtered piezoelectric material 128, a layer of the buffer material 124 provided over the epitaxially grown piezoelectric material 126 (the buffer layer material may also be epitaxially grown), a layer of the III-N channel material 112 over the buffer layer material 124, a layer of the polarization material 114 over the III-N channel material 112, and a layer of the hard-mask material 132 (e.g., SiN). The layers deposited in the process 314 may include materials and have thicknesses as described above with reference to these portions of the IC structure 100.

The method 300 may conclude with patterning the transistor films deposited in the process 314 and finishing transistor and resonator fabrication to form an IC structure having an III-N transistor integrated with an RF resonator as described herein (process 316 shown in FIG. 3, a result of which is not illustrated in FIG. 4 because the result could be, e.g., the IC structure 100 shown in FIG. 1 or the IC structure 200 shown in FIG. 2). The process 314 may include providing S/D regions, S/D contacts, a gate stack, etc., to arrive at the desired IC structure.

The S/D regions 116 may be formed using an implantation/diffusion process or an etching/deposition process, for example. In the former process, dopants such as silicon, germanium (where silicon and germanium are N-type dopants for III-N materials), boron, aluminum, antimony, phosphorous, or arsenic may be ion-implanted into the stack of the hard-mask material 132, the polarization material 114, and the III-N channel material 112 to form the S/D regions 116. An annealing process that activates the dopants and causes them to diffuse farther into the stack of the hard-mask material 132, the polarization material 114, and the III-N channel material 112 may follow the ion-implantation process. In the latter process, the stack of the hard-mask material 132, the polarization material 114, and the III-N channel material 112 may first be etched to form recesses at the locations of the S/D regions 116. An epitaxial deposition process may then be carried out to fill the recesses with material that is used to fabricate the S/D regions 116. In some implementations, the S/D regions 116 may be fabricated using an III-V alloy such as indium gallium nitride and gallium nitride. In some embodiments, the epitaxially deposited III-V alloy may be doped in situ with dopants such as silicon, germanium, boron, arsenic, or phosphorous. In some embodiments, the S/D regions 116 may be formed using one or more alternate semiconductor materials such as germanium or a group III-V material or alloy. In further embodiments, one or more layers of metal and/or metal alloys may be used to form the S/D regions 116.

Example Structures and Devices with III-N Transistors Integrated with RF Resonators

IC structures that include one or more III-N transistors integrated with one or more resonators of RF filters as disclosed herein may be included in any suitable electronic device. FIGS. 5-8 illustrate various examples of devices and components that may include one or more III-N transistors integrated with one or more RF resonators as disclosed herein.

FIGS. 5A-5B are top views of a wafer 2000 and dies 2002 that may include one or more III-N transistors integrated with one or more RF resonators in accordance with any of the embodiments disclosed herein. In some embodiments, the dies 2002 may be included in an IC package, in accordance with any of the embodiments disclosed herein. For example, any of the dies 2002 may serve as any of the dies 2256 in an IC package 2200 shown in FIG. 6. The wafer 2000 may be composed of semiconductor material and may include one or more dies 2002 having IC structures formed on a surface of the wafer 2000. Each of the dies 2002 may be a repeating unit of a semiconductor product that includes any suitable IC (e.g., ICs including one or more III-N transistors integrated with one or more RF resonators as described herein). After the fabrication of the semiconductor product is complete (e.g., after manufacture of one or more III-N transistors integrated with one or more RF resonators as described herein, e.g., after manufacture of any embodiment of the IC structures 100 or 200), the wafer 2000 may undergo a singulation process in which each of the dies 2002 is separated from one another to provide discrete “chips” of the semiconductor product. In particular, devices that include one or more III-N transistors integrated with one or more RF resonators as disclosed herein may take the form of the wafer 2000 (e.g., not singulated) or the form of the die 2002 (e.g., singulated). The die 2002 may include one or more transistors (e.g., one or more III-N transistors 102 as described herein), one or more resonators (e.g., one or more RF resonators 104 as described herein) as well as, optionally, supporting circuitry to route electrical signals to the III-N transistors and RF resonators, as well as any other IC components. In some embodiments, the wafer 2000 or the die 2002 may implement an RF FE device, a memory device (e.g., a SRAM device), a logic device (e.g., an AND, OR, NAND, or NOR gate), or any other suitable circuit element. Multiple ones of these devices may be combined on a single die 2002. For example, an RF filter array formed by multiple RF resonators may be formed on a same die 2002.

FIG. 6 is a side, cross-sectional view of an example IC package 2200 that may include one or more IC structures having one or more III-N transistors integrated with one or more RF resonators in accordance with any of the embodiments disclosed herein. In some embodiments, the IC package 2200 may be a system-in-package (SiP).

As shown in FIG. 6, the IC package 2200 may include a package substrate 2252. The package substrate 2252 may be formed of a dielectric material (e.g., a ceramic, a glass, a combination of organic and inorganic materials, a buildup film, an epoxy film having filler particles therein, etc., and may have embedded portions having different materials), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 6 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 6 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

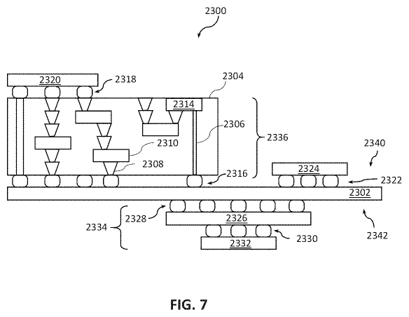

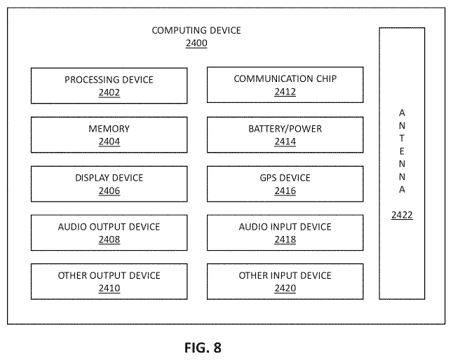

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 6 are solder balls (e.g., for a ball grid array arrangement), but any suitable second-level interconnects 22770 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 7.

The dies 2256 may take the form of any of the embodiments of the die 2002 discussed herein and may include any of the embodiments of an IC structure having one or more III-N transistors integrated with one or more RF resonators, e.g., any of the IC structures 100 or 200. In embodiments in which the IC package 2200 includes multiple dies 2256, the IC package 2200 may be referred to as a multi-chip package (MCP). Importantly, even in such embodiments of an MCP implementation of the IC package 2200, one or more III-N transistors integrated with one or more RF resonators in a single chip, in accordance with any of the embodiments described herein. The dies 2256 may include circuitry to perform any desired functionality. For example, one or more of the dies 2256 may be RF FE dies, including one or more III-N transistors integrated with one or more RF resonators in a single die as described herein, one or more of the dies 2256 may be logic dies (e.g., silicon-based dies), one or more of the dies 2256 may be memory dies (e.g., high bandwidth memory), etc.. In some embodiments, any of the dies 2256 may include one or more III-N transistors integrated with one or more RF resonators, e.g., as discussed above; in some embodiments, at least some of the dies 2256 may not include any III-N transistors integrated with RF resonators.

The IC package 2200 illustrated in FIG. 6 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 6, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 7 is a cross-sectional side view of an IC device assembly 2300 that may include components having one or more IC structures implementing one or more III-N transistors integrated with one or more RF resonators in accordance with any of the embodiments disclosed herein. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include any of the IC structures implementing one or more III-N transistors integrated with one or more RF resonators in accordance with any of the embodiments disclosed herein; e.g., any of the IC packages discussed below with reference to the IC device assembly 2300 may take the form of any of the embodiments of the IC package 2200 discussed above with reference to FIG. 6 (e.g., may include one or more III-N transistors integrated with one or more RF resonators in/on a die 2256).

In some embodiments, the circuit board 2302 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 7 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 7), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 5B), an IC device (e.g., the IC structure of FIGS. 1-2), or any other suitable component. In particular, the IC package 2320 may include one or more III-N transistors integrated with one or more RF resonators as described herein. Although a single IC package 2320 is shown in FIG. 7, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a wider pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 7, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other group III-V and group IV materials. The interposer 2304 may include metal interconnects 2308 and vias 2310, including but not limited to through-silicon vias (TSVs) 2306. The interposer 2304 may further include embedded devices 2314, including both passive and active devices. Such devices may include, but are not limited to, capacitors, decoupling capacitors, resistors, inductors, fuses, diodes, transformers, sensors, electrostatic discharge (ESD) protection devices, and memory devices. More complex devices such as further RF devices, PAs, power management devices, antennas, arrays, sensors, and microelectromechanical systems (MEMS) devices may also be formed on the interposer 2304. In some embodiments, the IC structures implementing one or more III-N transistors integrated with one or more RF resonators as described herein may also be implemented in/on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 7 includes a package-on-package structure 2334 coupled to the second face 2342 of the circuit board 2302 by coupling components 2328. The package-on-package structure 2334 may include an IC package 2326 and an IC package 2332 coupled together by coupling components 2330 such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

FIG. 8 is a block diagram of an example computing device 2400 that may include one or more components with one or more IC structures having one or more III-N transistors integrated with one or more RF resonators in accordance with any of the embodiments disclosed herein. For example, any suitable ones of the components of the computing device 2400 may include a die (e.g., the die 2002 (FIG. 5B)) including one or more III-N transistors integrated with one or more RF resonators in accordance with any of the embodiments disclosed herein. Any of the components of the computing device 2400 may include an IC device (e.g., the IC structure of FIGS. 1-2) and/or an IC package 2200 (FIG. 6). Any of the components of the computing device 2400 may include an IC device assembly 2300 (FIG. 7).

A number of components are illustrated in FIG. 8 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single SoC die.

Additionally, in various embodiments, the computing device 2400 may not include one or more of the components illustrated in FIG. 8, but the computing device 2400 may include interface circuitry for coupling to the one or more components. For example, the computing device 2400 may not include a display device 2406, but may include display device interface circuitry (e.g., a connector and driver circuitry) to which a display device 2406 may be coupled. In another set of examples, the computing device 2400 may not include an audio input device 2418 or an audio output device 2408, but may include audio input or output device interface circuitry (e.g., connectors and supporting circuitry) to which an audio input device 2418 or audio output device 2408 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid state memory, and/or a hard drive. In some embodiments, the memory 2404 may include memory that shares a die with the processing device 2402. This memory may be used as cache memory and may include, e.g., eDRAM, and/or spin transfer torque magnetic random-access memory (STT-M RAM).

In some embodiments, the computing device 2400 may include a communication chip 2412 (e.g., one or more communication chips). For example, the communication chip 2412 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2412 may operate in accordance with other wireless protocols in other embodiments. The computing device 2400 may include an antenna 2422 to facilitate wireless communications and/or to receive other wireless communications (such as AM or FM radio transmissions).

In some embodiments, the communication chip 2412 may manage wired communications, such as electrical, optical, or any other suitable communication protocols (e.g., the Ethernet). As noted above, the communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

In various embodiments, IC structures as described herein may be particularly advantageous for use within the one or more communication chips 2412, described above. For example, such IC structures may be used to implement one or more of power amplifiers, low-noise amplifiers, filters (including arrays of filters and filter banks), switches, upconverters, downconverters, and duplexers, e.g., as a part of implementing an RF transmitter, an RF receiver, or an RF transceiver.

The computing device 2400 may include battery/power circuitry 2414. The battery/power circuitry 2414 may include one or more energy storage devices (e.g., batteries or capacitors) and/or circuitry for coupling components of the computing device 2400 to an energy source separate from the computing device 2400 (e.g., AC line power).

The computing device 2400 may include a display device 2406 (or corresponding interface circuitry, as discussed above). The display device 2406 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2408 (or corresponding interface circuitry, as discussed above). The audio output device 2408 may include any device that generates an audible indicator, such as speakers, headsets, or earbuds, for example.

The computing device 2400 may include an audio input device 2418 (or corresponding interface circuitry, as discussed above). The audio input device 2418 may include any device that generates a signal representative of a sound, such as microphones, microphone arrays, or digital instruments (e.g., instruments having a musical instrument digital interface (MIDI) output).

The computing device 2400 may include a GPS device 2416 (or corresponding interface circuitry, as discussed above). The GPS device 2416 may be in communication with a satellite-based system and may receive a location of the computing device 2400, as known in the art.

The computing device 2400 may include an other output device 2410 (or corresponding interface circuitry, as discussed above). Examples of the other output device 2410 may include an audio codec, a video codec, a printer, a wired or wireless transmitter for providing information to other devices, or an additional storage device.

The computing device 2400 may include an other input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

### SELECT EXAMPLES

The following paragraphs provide various examples of the embodiments disclosed herein.

Example 1 provides an IC structure that includes a support structure (e.g., a substrate), a RF resonator provided over a first portion of the support structure, and an III-N transistor provided over a second portion of the support structure.

Example 2 provides the IC structure according to example 1, where the RF resonator includes a bottom electrode, a top electrode, a piezoelectric material provided between the bottom electrode and the top electrode, a cavity surrounding at least a portion of the bottom electrode, and a cavity surrounding at least a portion of the top electrode.

Example 3 provides the IC structure according to example 2, where the piezoelectric material includes aluminum and nitrogen (e.g., AlN).

Example 4 provides the IC structure according to examples 2 or 3, where a thickness of the piezoelectric material provided between the bottom electrode and the top electrode is between about 100 and 2000 nanometers.

Example 5 provides the IC structure according to any one of the preceding examples, where the III-N transistor includes an III-N channel material, and a polarization material (e.g., a semiconductor material having stronger piezo-polarization behavior/properties than the III-N channel material), where at least a portion of the polarization material forms a heterojunction interface with at least a portion of the III-N channel material.

Example 6 provides the IC structure according to example 5, where the III-N channel material includes gallium and nitrogen (e.g., GaN).

Example 7 provides the IC structure according to examples 5 or 6, where a thickness of the III-N channel material is between about 5 and 100 nanometers, e.g., between about 10 and 50 nanometers.

Example 8 provides the IC structure according to any one of examples 5-7, where the polarization material includes aluminum, indium, gallium, and nitrogen (e.g., AlₓIn_{y}Ga_{z}N).

Example 9 provides the IC structure according to any one of examples 5-8 , where a thickness of the polarization material is between about 2 and 50 nanometers, e.g., between about 10 and 30 nanometers.

Example 10 provides the IC structure according to any one of examples 5-9, where the III-N transistor further includes a buffer material provided between the III-N channel material and the support structure, where a bandgap of the buffer material is greater than a bandgap of the III-N cannel material.

Example 11 provides the IC structure according to example 10, where the buffer material includes a material including aluminum, gallium, and nitrogen (e.g., AlGaN), or a material including aluminum and nitrogen (e.g., AlN).

Example 12 provides the IC structure according to examples 10 or 11, where a thickness of the buffer material is between about 100 and 5000 nanometers, e.g., between about 250 and 500 nanometers.

Example 13 provides the IC structure according to any one of the preceding examples, further including a sputtered III-N material provided between the support structure and the III-N channel material, and an epitaxially grown III-N material provided between the sputtered III-N material and the III-N channel material.

Example 14 provides the IC structure according to example 13, where a thickness of the epitaxially grown III-N material between the sputtered III-N material and the III-N channel material is between about 10 and 200 nanometers, e.g., between about 20 and 50 nanometers.

Example 15 provides the IC structure according to examples 13 or 14, where a thickness of the sputtered III-N material between the support structure and the III-N channel material is between about 100 and 2000 nanometers.

Example 16 provides the IC structure according to any one of examples 13-15, where the epitaxially grown III-N material is a single crystalline material, possibly defective, i.e., including a certain amount of dislocations.

Example 17 provides the IC structure according to any one of examples 13-16, where the sputtered III-N material includes a plurality of different crystalline domains (i.e., the sputtered III-N material is not a single crystalline material).

Example 18 provides the IC structure according to any one of examples 13-17, where a FWHM of an X-ray diffraction peak of the epitaxially grown III-N material is less than about 2 degrees.

Example 19 provides the IC structure according to any one of examples 13-18, where a FWHM of an X-ray diffraction peak of the sputtered III-N material is equal to or greater than about 2 degrees.

Example 20 provides the IC structure according to any one of the preceding examples, where the RF resonator is one of a plurality of RF resonators included in the IC structure.

Example 21 provides the IC structure according to any one of the preceding examples, further including one or more insulator materials between one or more of the following the RF resonator and the support structure, the III-N transistor and the support structure, and the RF resonator and the III-N transistor.

Example 22 provides the IC structure according to any one of the preceding examples, where the support structure is a substrate.

In various further examples, the IC structure according to any one of the preceding examples may be included in, or used to implement at least a portion of, an RF FE.

Example 23 provides an IC package that includes an IC die and a further IC component, coupled to the IC die. The IC die includes a support structure (e.g., substrate material), a piezoelectric material provided over the support structure, a RF resonator provided over a first portion of the support structure, where the RF resonator includes a first and a second electrodes, and a first portion of the piezoelectric material between the first and the second electrodes, an III-N transistor provided over a second portion of the support structure, where a second portion of the piezoelectric material is between the III-N transistor and the support structure.

Example 24 provides the IC package according to example 23, where the further IC component includes one of a package substrate, an interposer, or a further IC die.

Example 25 provides the IC package according to examples 23 or 24, where the piezoelectric material is an III-N semiconductor material, e.g., a material including aluminum and nitrogen (e.g., AlN).

Example 26 provides the IC package according to any one of examples 23-25, where the piezoelectric material includes a plurality of different crystalline domains (i.e., the piezoelectric material is not a single crystalline material).

Example 27 provides the IC package according to any one of examples 23-26, where a FWHM of an X-ray diffraction peak of the piezoelectric material is equal to or greater than 2 degrees.

Example 28 provides the IC package according to any one of examples 23-27, where a thickness of the piezoelectric material is between about 100 and 2000 nanometers.

Example 29 provides the IC package according to any one of examples 23-28, where the III-N transistor includes an III-N channel material and a polarization material (e.g., a semiconductor material having stronger piezo-polarization behavior/properties than the III-N channel material), where at least a portion of the polarization material may form a heterojunction interface with at least a portion of the III-N channel material, the piezoelectric material is a first piezoelectric material, and the IC die further includes a second piezoelectric material between the first piezoelectric material and the III-N channel material.

Example 30 provides the IC package according to example 29, where the second piezoelectric material is an III-N semiconductor material, e.g., a material including aluminum and nitrogen (e.g., AlN).

Example 31 provides the IC package according to examples 29 or 30, where the second piezoelectric material is a single crystalline material, possibly defective, i.e., including a certain amount of dislocations.

Example 32 provides the IC package according to any one of examples 29-31, where a FWHM of an X-ray diffraction peak of the second piezoelectric material is less than 2 degrees.

Example 33 provides the IC package according to any one of examples 29-32, where a thickness of the second piezoelectric material is between about 10 and 200 nanometers, e.g., between about 20 and 50 nanometers.

Example 34 provides the IC package according to any one of the preceding examples, where the IC die includes the IC structure according to any one of the preceding examples, e.g., the IC structure according to any one of examples 1-22.

Example 35 provides an IC structure that includes a support structure (e.g., a substrate) and a transistor. The transistor includes an III-N channel material, and a gate stack. The gate stack includes a gate electrode material and a dielectric material between the gate electrode material and the channel material. The transistor further includes a sputtered III-N material between the III-N channel material and the support structure, and an epitaxially grown III-N material between the III-N channel material and the sputtered III-N material.

Example 36 provides the IC structure according to example 35, where a FWHM of an X-ray diffraction peak of the epitaxially grown III-N material is less than 2 degrees.

Example 37 provides the IC structure according to examples 35 or 36, where a FWHM of an X-ray diffraction peak of the sputtered III-N material is equal to or greater than 2 degrees.

Example 38 provides the IC structure according to any one of examples 35-37, where a thickness of the epitaxially grown III-N material between the sputtered III-N material and the III-N channel material is between about 10 and 200 nanometers, e.g., between about 20 and 50 nanometers.

Example 39 provides the IC structure according to any one of examples 35-38, where a thickness of the sputtered III-N material between the support structure and the III-N channel material is between about 100 and 2000 nanometers.

Example 40 provides the IC structure according to any one of examples 35-39, where the epitaxially grown III-N material is a single crystalline material, possibly defective, i.e., including a certain amount of dislocations.

Example 41 provides the IC structure according to any one of examples 35-40, where the sputtered III-N material includes a plurality of different crystalline domains (i.e., the sputtered III-N material is not a single crystalline material).

Example 42 provides the IC structure according to any one of examples 35-41, where the transistor further includes a source region and a drain region.

Example 43 provides the IC structure according to any one of examples 35-42, where the transistor is in a RF FE.

Example 44 provides the IC structure according to any one of examples 35-43, where the transistor is the III-N transistor of the IC structure according to any one of examples 1-22.

Example 45 provides an IC package that includes an IC die, the IC die including the IC structure according to any one of examples 35-44; and a further IC component, coupled to the IC die.

Example 46 provides the IC package according to example 45, where the further IC component includes one of a package substrate, an interposer, or a further IC die.

Example 47 provides a computing device that includes a carrier substrate and an IC die coupled to the carrier substrate, where the IC die includes the IC structure according to any one of examples 1-22 or the IC structure according to any one of examples 35-44, and/or the IC die is included in the IC package according to any one of examples 23-34 or the IC package according to any one of examples 25-46.

Example 48 provides the computing device according to example 47, where the computing device is a wearable or handheld computing device.

Example 49 provides the computing device according to examples 47 or 48, where the computing device further includes one or more communication chips and an antenna.

Example 50 provides the computing device according to any one of examples 47-49, where the carrier substrate is a motherboard.

Example 51 provides a method of manufacturing an IC structure, the method including providing a piezoelectric material over a support structure, providing a RF resonator, where the RF resonator includes a first and a second electrodes, and a first portion of the piezoelectric material between the first and the second electrodes, and providing an III-N transistor, where a second portion of the piezoelectric material is between the III-N transistor and the support structure.

Example 52 provides the method according to example 51, where providing the piezoelectric material includes performing sputtering to provide the piezoelectric material.

Example 53 provides the method according to example 52, where providing the III-N transistor includes providing an III-N channel material of the III-N transistor, the piezoelectric material is a first piezoelectric material, and the method further includes epitaxially growing a second piezoelectric material over the first piezoelectric material (i.e., over the sputtered piezoelectric material), where the second piezoelectric material is between the first piezoelectric material and the III-N channel material.

Example 54 provides the method according to any one of examples 51-53, where the IC structure is the IC structure according to any one of examples 1-22 or the IC structure according to any one of examples 35-44, and the method includes corresponding further processes to manufacture any of these IC structures.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) structure, comprising:
a support structure;
a radio frequency (RF) resonator over a first portion of the support structure; and
an III-N transistor over a second portion of the support structure.

2. The IC structure according to claim 1, wherein the RF resonator includes:
a bottom electrode,
a top electrode,
a piezoelectric material between the bottom electrode and the top electrode,
a cavity surrounding at least a portion of the bottom electrode, and
a cavity surrounding at least a portion of the top electrode.

3. The IC structure according to claim 2, wherein the piezoelectric material includes aluminum and nitrogen.

4. The IC structure according to claim 2, wherein a thickness of the piezoelectric material between the bottom electrode and the top electrode is between 100 and 2000 nanometers.

5. The IC structure according to claim 1, wherein the III-N transistor includes:
an III-N channel material, and
a polarization material,
where at least a portion of the polarization material forms a heterojunction interface with at least a portion of the III-N channel material.

6. The IC structure according to claim 5, wherein the III-N channel material includes gallium and nitrogen.

7. The IC structure according to claim 5, wherein a thickness of the III-N channel material is between 5 and 100 nanometers.

8. The IC structure according to claim 5, wherein the III-N transistor further includes a buffer material between the III-N channel material and the support structure, wherein a bandgap of the buffer material is greater than a bandgap of the III-N cannel material.

9. The IC structure according to claim 8, wherein a thickness of the buffer material is between 250 and 500 nanometers.

10. The IC structure according to claim 1, further comprising:
a sputtered III-N material between the support structure and the III-N channel material, and
an epitaxially grown III-N material between the sputtered III-N material and the III-N channel material.

11. The IC structure according to claim 10, wherein a thickness of the epitaxially grown III-N material between the sputtered III-N material and the III-N channel material is between 10 and 200 nanometers.

12. The IC structure according to claim 10, wherein a thickness of the sputtered III-N material between the support structure and the III-N channel material is between 100 and 2000 nanometers.

13. The IC structure according to claim 10, wherein a full width half maximum of an X-ray diffraction peak of the epitaxially grown III-N material is equal to or less than 2 degrees.

14. The IC structure according to claim 10, wherein a full width half maximum (FWHM) of an X-ray diffraction peak of the sputtered III-N material is greater than a FWHM of an X-ray diffraction peak of the epitaxially grown III-N material.

15. The IC structure according to claim 1, wherein the RF resonator is one of a plurality of RF resonators included in the IC structure.

16. The IC structure according to claim 1, further comprising one or more insulator materials between one or more of the following:
the RF resonator and the support structure,
the III-N transistor and the support structure, and
the RF resonator and the III-N transistor.

17. An integrated circuit (IC) package, comprising:
an integrated circuit (IC) die, including:
a support structure,
a piezoelectric material over the support structure,
a radio frequency (RF) resonator over a first portion of the support structure, where the RF resonator includes a first and a second electrodes, and a first portion of the piezoelectric material between the first and the second electrodes,
an III-N transistor over a second portion of the support structure, where a second portion of the piezoelectric material is between the III-N transistor and the support structure; and
a further IC component, coupled to the IC die.

18. The IC package according to claim 17, wherein the further IC component includes one of a package substrate, an interposer, or a further IC die.

19. An integrated circuit (IC) structure, comprising:
a support structure; and
a transistor, the transistor including:
an III-N channel material,
a gate stack, including a gate electrode material, and a dielectric material between the gate electrode material and the channel material,
a sputtered III-N material between the III-N channel material and the support structure, and
an epitaxially grown III-N material between the III-N channel material and the sputtered III-N material.

20. The IC structure according to claim 19, wherein a thickness of the epitaxially grown III-N material between the sputtered III-N material and the III-N channel material is between 20 and 50 nanometers, and wherein a thickness of the sputtered III-N material between the support structure and the III-N channel material is between 100 and 2000 nanometers.
